(19) United States
(12) Patent Application Publication
(10) Pub. No.: US 2011/0186119 A1
(43) Pub. Date: Aug. 4, 2011

(54) Light-trapping plasmonic back reflector design for solar cells

(76) Inventors: Harry A. Atwater, South Pasadena, CA (US); Vivian Ferry, Pasadena, CA (US); Albert Polman, Amsterdam (NL); Ruud Schropp, Driebergen (NL); Marc Verschuuren, Tilburg (NL)

(21) Appl. No.: 12/928,964

(22) Filed: Dec. 23, 2010

Related U.S. Application Data
(60) Provisional application No. 61/290,129, filed on Dec. 24, 2009.

(51) Int. Cl. H01L 31/0232; H01L 31/0352

(52) U.S. Cl. 136/256; 438/87; 257/E31.032

(57) ABSTRACT

A solar cell includes a nano-scale patterned back contact layer; a spacer layer on the nano-scale patterned back contact layer; a semiconductor layer on the spacer layer; and a light transmissive first electrode on the semiconductor layer.

### CROSS-REFERENCE TO RELATED APPLICATION

This application claims priority to and the benefit of U.S. Provisional Patent Application No. 61/290,129 filed on Dec. 24, 2009 and U.S. Provisional Application No. 61/380,190 filed on Sep. 3, 2010 in the United States Patent and Trademark Office, the entire contents of which are incorporated herein by reference.

### STATEMENT REGARDING FEDERALLY SPONSORED RESEARCH OR DEVELOPMENT

The U.S. Government has certain rights in this invention pursuant to Grant No. DE-FG02-07ER46405 DOE #S-122,120 awarded by the DOE.

### BACKGROUND

Conventional solar cell absorbing layers are “optically thick” in order to increase efficiency. That is, to generate sufficient photocurrent, the semiconductor region should be thick enough to absorb nearly all of the incident sunlight. However, at the same time, the carriers generated by absorption should be efficiently collected by the cell, which for most materials systems corresponds to thickness of the semiconductor being several times smaller than the minority carrier diffusion lengths. These competing demands on the cell thickness drive much of solar cell design and material synthesis.

Thinner semiconductor regions differ from their thicker counterparts in ways which have important technical and strategic implications for the scaling up of photovoltaic production capability. For standard and well-established thin film technologies such as amorphous Si (a-Si:H), cadmium telluride (CdTe), and copper indium gallium diselenide (CIGS), reduced thickness reduces the deposition time per device, which increases manufacturing throughput. This reduced deposition time is particularly beneficial for a-Si:H because plasma enhanced chemical vapor deposition (PECVD), one of the standard growth methods for high quality a-Si:H cells, has a relatively slow growth rate which limits the manufacturing throughput of a-Si:H devices. In addition, the reduced thickness reduces the quantity of raw material needed to make a given device. This both reduces costs for common feedstock materials (such as silane for a-Si:H deposition) and improves the scalability of devices based on rare, scarce elements such as Te and In that are essential for CdTe and CIGS. For example, the quantity of Te and In required to expand worldwide production by photovoltaics to 50 gigawatts (GW) by 2020 using conventionally designed CdTe or CIGS exceeds their annual worldwide production by an order of magnitude. Reducing the thickness of these layers by a factor of 10 or 100 would extend the reach of these compound semiconductors to the terawatt scale.

For less well-established thin film technologies, the use of thinner films tolerates lower quality films. Given that the carrier diffusion lengths are generally several times the device thickness for efficient carrier collection, thinner films can tolerate more defects and impurities. Materials such as quantum dots, polymers, small molecules, and unusual semiconductors such as Zn₃P₄ that are less well-characterized could be used in these thinner geometries. This tolerance for lower quality films also means that lower quality, inexpensive production methods for established semiconductors could be used.

Specifically, for a-Si:H, thinner semiconductor regions can also improve stability of the device under light illumination. Hydrogenated amorphous Si films (a-Si:H) generally degrade under light illumination (referred to as the Staebler-Wronski effect). Cells based on a-Si:H are typically made as n-i-p devices, where the electric field across the intrinsic region (i) from the doped n and p type layers improves carrier collection. When the intrinsic layer is extremely thin, the higher electric field across the region mitigates the effect of degradation, and the device is stable under illumination.

Thinner semiconductor regions can also improve the electrical characteristics of the cell. For materials that are not dominated by surface recombination, decreasing the thickness reduces the dark current in the cell, which in turn increases the open circuit voltage of the device logarithmically. Thus, provided that the level of absorption remains the same between ultrathin cells and their thicker counterparts, the efficiency of the device could increase due to the thickness reduction.

In standard thick films, light that enters the absorbing region is absorbed exponentially. Each semiconductor has wavelength-dependent absorption coefficients that describe the strength of light absorption. Blue light is absorbed within a fairly short length, while the longer red wavelengths, particularly near the bandgap of the semiconductor, may take the entire thickness of the thick film to be absorbed. Placing a mirror on the back of the semiconductor film doubles the path length of the light. Adding surface features such as pyramids can scatter the light at the interfaces into a wider distribution of angles inside the semiconductor film, thereby further increasing the path length and trapping light within the absorbing region. Theoretically, a maximum enhancement of 4n² is possible in this thick film limit, where n is the refractive index of the semiconductor near the band edge of the semiconductor where absorption is weak. This maximum could be achieved using a random surface texture in the solar cell.

However, in the case of thin and ultrathin films this maximum does not apply, and wavelength-size features are inappropriate for thin film devices for both geometric reasons and because the increased surface area increases minority carrier recombination. Nevertheless, the conventional approach for light trapping in thin film technologies is to use random nanoscale surface textures. Light trapping is useful in improving the efficiency of a-Si:H solar cells, where the cells are typically intentionally made thin for more efficient carrier collection and stability, as mentioned above. Conventional methods for including roughness include both substrate-type and superstrate-type texturing. Substrate roughness is often formed via hot sputtering of Ag or Al and ZnO:Al to form the back contact. Superstrate-type roughness is often from textured conducting metal-oxide films, such as atmospheric pressure chemical vapor deposition (CVD) of SnO₂:F or low pressure CVD deposition of ZnO:Al. Roughness has also been incorporated from electrically passive materials such as plastic substrates and glass superstrates.

Surface plasmons—the oscillation of the conduction electrons on the surface of a metal and a dielectric—have attracted attention for use in a variety of applications due to their ability to guide and confine light in nanoscale dimensions. Surface plasmons may refer to either localized plasmons, which are confined to the surface of a particular nanostructure, or to surface plasmon polaritons, which are waveguide modes at the interface of a planar film and a second material.

Plasmonic metal nanostructures with localized surface plasmon modes are notable for their high scattering cross sections: incident light may be scattered from an effective volume several times the physical cross section of the nanostructure. These scattering cross sections depend on the shape and size of the nanostructure, the metal, and the surrounding medium, and are particularly strong at a resonant frequency. Absorption cross sections, which represent loss in the metal, can also be strong. Typically small metal features are dominated by absorption, and bigger metal features are dominated by scattering, until the nanostructure becomes too large and higher order modes are excited.

Thin semiconductor films also support propagating waveguide modes, which depend on wavelength and polarization. Once a waveguide mode is excited, it propagates in the plane of the device. These waveguide modes are momentum-mismatched from incident light, so an incoupling nanostructure or scattering object is necessary to couple light into the propagating mode. For most applications, such as telecommunications, the waveguide is designed to be as low-loss as possible so that the mode reaches the next component. In the case of a solar cell, however, the power in the mode is absorbed while it propagates, with some fraction of that absorption generating photocurrent in the semiconductor.

### SUMMARY

Aspects of embodiments of the present invention are directed to light-trapping plasmonic back reflectors for ultrathin a-Si:H solar cells which are capable of increasing the efficiency of the solar cells. These light-trapping plasmonic back reflectors provide increased efficiency over randomly patterned rough back reflectors in solar cells with thin semiconductor layers.

According to one embodiment of the present invention, a solar cell includes a nano-scale patterned back contact layer; a spacer layer on the nano-scale patterned back contact layer; a semiconductor layer on the spacer layer; and a light transmissive first electrode on the semiconductor layer.

According to another embodiment of the present invention, a method of manufacturing a solar cell includes: depositing a metal onto a nano-scale patterned mold to form a nano-scale patterned metal layer; depositing a spacer layer onto the nano-scale patterned metal layer; depositing n-i-p semiconductor layers on the spacer layer; depositing an array of squares of a transparent conductive layer through a first contact mask to form a transparent conductor layer; and depositing a plurality of finger contacts over the transparent conductive layer using a second contact mask.

One design challenge is to preferentially couple to the modes that are absorbed primarily in the semiconductor, while avoiding coupling to those that are mainly absorbed in the metal or cladding regions.

The use of plasmonics in solar cells to enhance absorption is counter-intuitive, for at least the following reasons:

(1) Plasmonic nanostructures are lossy and parasitically absorb sunlight. For randomly roughened back reflectors as commonly used in a-Si:H, this can be true since the small metal features are dominated by absorption losses rather than scattering.

(2) Scattering cross sections are narrow band, so it is difficult for plasmonics to enhance photocurrent over large spectral ranges.

(3) Adding metal to a solar cell can increase recombination losses.

Most plasmonic solar cells to date use isolated metal islands, typically on the front surface of an already-fabricated solar cell. These metal islands have large scattering cross sections and preferentially scatter incident light downward, into the semiconductor, with an increased path length. The metal islands can also be placed on the back of the cell (provided there is no back reflector), and work similarly scattering light upward into the semiconductor. Although these designs can lead to overall photocurrent and efficiency enhancements, they often suffer from (2) above: the enhancement is usually confined to the band edge region, and there are frequently decreases in photocurrent on the blue side of the spectrum.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings, together with the specification, illustrate exemplary embodiments of the present invention, and, together with the description, serve to explain the principles of the present invention.

FIG. 1 is a somewhat diagrammatic perspective view of a nano-scale patterned plasmonic solar cell according to an embodiment of the present invention, showing the front and left edges in vertical cross section.

FIGS. 2A and 2B are graphs comparing experimental and simulated external quantum efficiencies of solar cells having a rough texture and nano-scale patterns, respectively, according to embodiments of the present invention.

FIG. 3 is a graph comparing simulated carrier generation rates of solar cells according to embodiments of the present invention with a rough back contact layer and a nano-scale patterned back contact layer while maintaining nano-scale patterns in the spacer, semiconductor, and first electrode layers.

FIG. 4 is a graph comparing simulated normalized carrier generation rates of solar cells according to embodiments of the present invention when the back contact layer is gold, silver, copper, and aluminum.

FIG. 5A is a graph illustrating absorption enhancement as a function of pitch and incident wavelength, where the enhancement is calculated relative to the absorption in a simulated Asahi reference cell according to embodiments of the present invention.

FIG. 5B is a graph of solar spectrum integrated enhancement in absorption as a function of pitch for a solar cell with a back contact layer having nano-scale features 300 nm in diameter according to embodiments of the present invention.

FIG. 6A is a graph comparing the calculated reflectances of solar cells in which only the top surfaces are textured. The compared surfaces are flat, rough (Asahi glass texture), and nano-scale structures having 700 nm, 500 nm, and 400 nm pitches according to embodiments of the present invention.

FIG. 6B is a graph illustrating the change in reflection as the height of the nano-scale structures (or “cone”) is varied from 0 nm (flat film) to 500 nm at various wavelengths according to embodiments of the present invention.

FIG. 7 is a graph illustrating simulated solar spectrum weighted enhancement calculated for nano-scale features in a range of diameters from 100 nm to 400 nm, where the pitch of the nano-scale features is chosen to maximize the calculated enhancement for each diameter according to embodiments of the present invention.

FIG. 8 is a flowchart illustrating a method of forming a nano-scale patterned mold according to an embodiment of the present invention.

FIG. 9 is a flowchart illustrating a method of fabricating a plasmonic solar cell according to an embodiment of the present invention.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

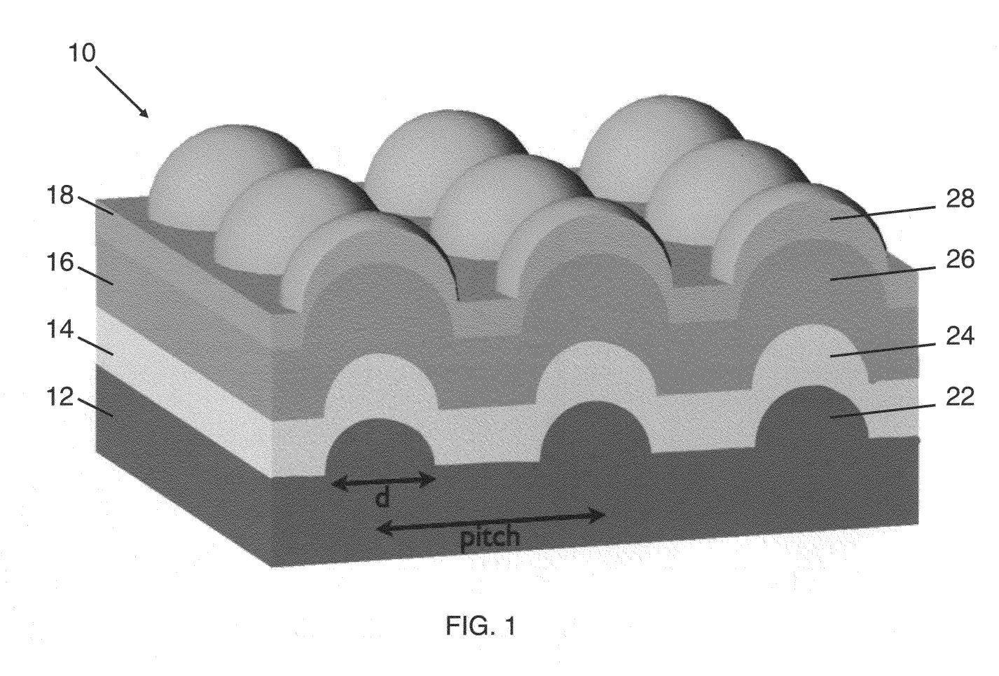

Referring to FIG. 1, a plasmonic solar cell 10 according to embodiments of the present invention includes metal nanostructures 22 which may be built directly into the back metal contact 12 of the solar cell 10, with the aim of increasing the efficiency of solar cells having thin film semiconductor layers by coupling incident light energy into waveguide modes of the cell. The light in the blue (shorter wavelength) portion of the spectrum is generally absorbed in the “upper” layers of the cell (e.g., the semiconductor layer 16) before reaching the back metal contact 12 and the light in the redder (longer wavelength) portion of the spectrum is scattered by the designed nanostructures (22, 24, 26, and 28) of the layers of the plasmonic solar cell and coupled into both localized modes and waveguide modes of the cell. The waveguide modes propagate in the plane of the solar cell and lead to increased photocurrent as they are absorbed in the semiconductor 16. The localized modes are also absorbed predominantly in the semiconductor 16.

Several aspects of the present invention allow it to address or mitigate the three issues discussed above in the background related to the use of plasmonics in solar cells:

(1) The shape and size of the nanostructures can be designed to increase scattering and decrease losses due to parasitic absorption. As illustrated in the embodiment shown in FIG. 1, the nanostructural features (or nano-scale features) may be rounded cylinders or hemispheres, which reduce losses due to sharp corners. Unlike the random texture designs, the shape and arrangement of the features are precisely controlled and generally do not include small feature components that predominantly absorb light. As a result, the current collection efficiency is increased over random texture designs. A conducting spacer layer 14 (which may include ZnO:Al) may be included between the semiconductor (such as an a-Si:H layer) and the metal back contact (such as a silver, gold, copper, aluminum, etc layer) to decrease coupling to parasitic surface plasmon polariton modes.

(2) Several features of the design can also be used to increase the bandwidth of the photocurrent. The scattering cross section of the particle (or a nano-scale feature) increases coupling to waveguide modes on the red side of the spectrum. Localized absorption modes also increase photocurrent. In addition to the back metal pattern, the top conducting oxide/semiconductor (ITO/a-Si:H) interface is also nanostructured, and these patterns are designed to enhance absorption on the blue side of the spectrum. The pitch and arrangement of the nanostructures has been designed to improve efficiency for both the front and back surfaces.

(3) No additional metal is added in this design because the metal back contact is already present in the device. The metal may also be isolated from the semiconductor via a conducting spacer layer, which decreases direct recombination losses.

Referring to FIG. 1, as described above, a plasmonic solar cell according to an embodiment of the present invention includes a nano-scale patterned back contact layer 12. This nano-scale patterned back contact layer includes a plurality of nano-scale features 22 such as rounded cylinders, hemispheres, spherical caps, and similar structures having a diameter d and spaced apart from one another at a pitch. As used here, “diameter” is defined as being the longest distance between two points at the edges of the nano-scale feature in a plan view (i.e., when viewed from above) and “pitch” is defined as the distance between adjacent nano-scale features as measured between their center points in a plan view. The nano-scale back contact layer may be metallic and may include a metal such as silver.

The plasmonic solar cell 10 also includes a spacer layer 14 on the nano-scale patterned back contact layer. The spacer layer may also include nano-scale features 24 similar to the nano-scale features 22 of the back-contact layer 12. These nano-scale features 24 of the spacer layer 14 may have a diameter larger than the diameter of the nano-scale features 22 of the back-contact layer 12. The spacer layer may include a transparent conductive material such as ZnO:Al.

Above the spacer layer 14 of the plasmonic solar cell 10 is a semiconductor layer 16. The semiconductor layer may include a semiconductor such as a-Si:H, CIGS, or CdTe and these materials are doped to form a p-i-n junction, n-i-p junction, or a p-n junction, as appropriate for the type of semiconductor used. The semiconductor layer 16 may also include nano-scale features 26 similar in shape to the nano-scale features 24 and 22 of the layers below and may also have a diameter larger than the nano-scale features of 24 the spacer layer 14.

A first electrode 18 is located on top of the semiconductor layer. The first electrode includes a transparent conductive material such as indium tin oxide (ITO). The first electrode may also include a grid of a conductive material such as gold to reduce its resistance. Alternatively, the first electrode may include only a grid of conductive material without a conductive transparent material. The first electrode may also include nano-scale features 28 similar to the nano-scale features of the layers below and may have a diameter larger than the nano-scale features 26 of the semiconductor layer 16.

According to a first embodiment of the present invention, a solar cell has a silver (Ag) back contact layer 12 having substantially hemispherical nano-scale features 22 having a diameter of 300 nm at a pitch of 500 nm. The nano-scale features 24, 26, and 28 of a ZnO:Al spacer layer 14, an a-Si:H semiconductor layer 16, and an ITO first electrode are 325 nm, 375 nm, and 400 nm in diameter, respectively. The ITO first electrode is 80 nm thick, the spacer layer is 130 nm thick, and the semiconductor layer is 160 nm thick, with the p-layer being 20 nm thick, the n-layer being 25 layer thick, and the rest (115 nm) being intrinsic.

Although FIG. 1 illustrates the contours of the nano-scale features of the various layers as closely matching one another, depending on the method used to fabricate the solar cell, these contours may be smoothed or imperfectly replicated in later formed layers which are formed on (e.g., on top of) layers formed earlier in the process. Notwithstanding these imperfections, these structures will still be referred to nano-scale features, rounded cylinders, and the like.

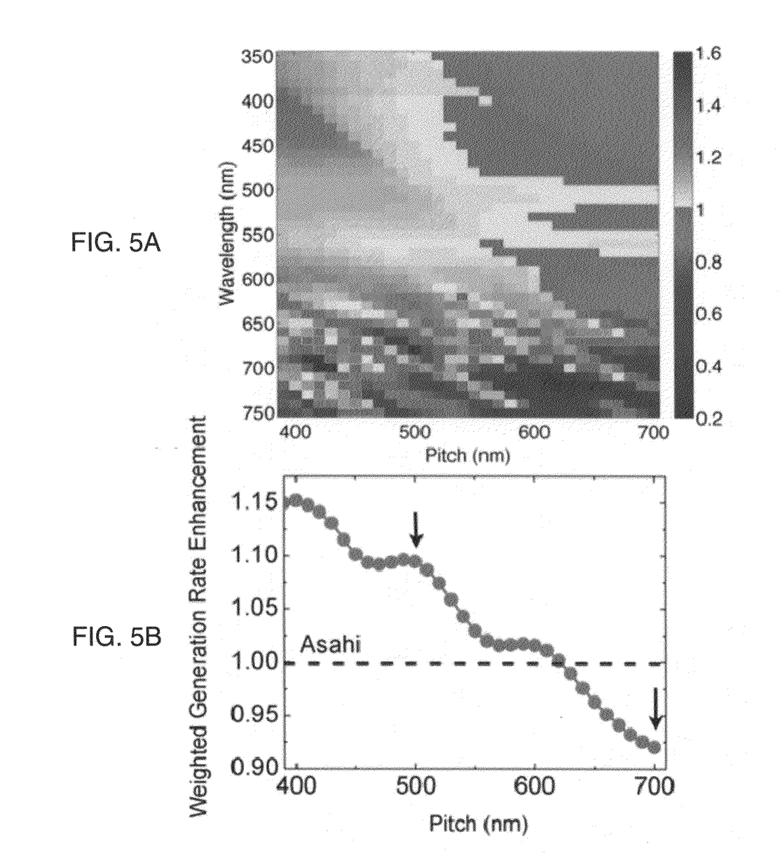

According to one embodiment of the present invention, the diameters of the fabricated Ag particles range from 200-300 nm. Larger size particles (e.g., 250-300 nm) may further increase performance. The top features in the ITO are close together or touching, but not overlapping in order to increase the curvature on the top surface; which governs a size range for the bottom particles. If the two interfaces are patterned separately this is not restrictive. For example, with 400 nm pitch between the particles, and 160 nm thick a-Si:H layer, the Ag may be 300 nm in diameter and the ITO patterns may be 400 nm in diameter. For example, FIGS. 5A and 5B (discussed in more’ detail below) illustrate the effect of pitch on absorbed energy for a given wavelength for a 300 nm particle of Ag based on simulations.

According to a comparative example, a solar cell was fabricated with the same materials and at the same thicknesses as in the above first embodiment, but on a randomly textured silver surface (Asahi U-type glass texture) such that the solar cell of the comparative example did not include the nano-scale features.

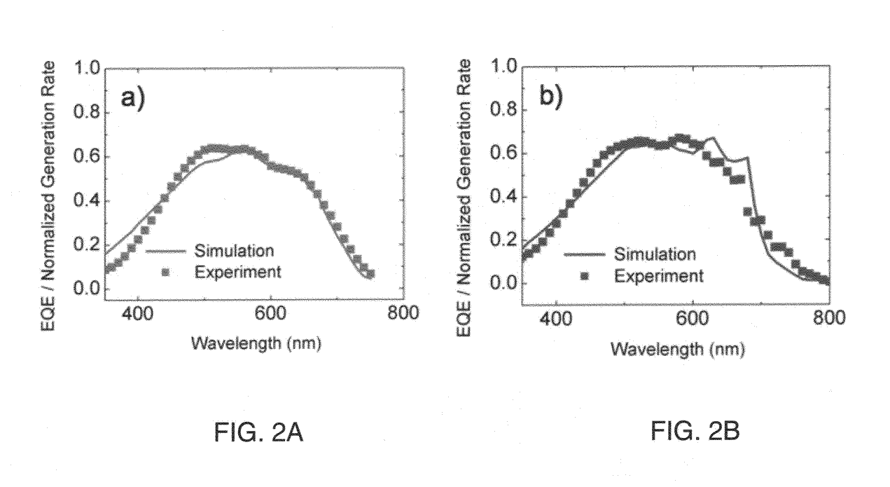

FIG. 2A is a graph of simulated and experimental external quantum efficiency as a function of wavelength for the above-described comparative example (having the rough surface). The same physical characteristics (e.g., thicknesses of the layers) were supplied to the simulation. The rough surface of the fabricated solar cell was imaged using atomic force microscopy for the purpose of performing the simulation.

FIG. 2B is a graph of simulated and experimental external quantum efficiency as a function of wavelength for the above described first embodiment of the present invention (having a plurality of nano-scale features in the back contact, spacer, semiconductor, and first electrode layers). As above in FIG. 2B, the same physical characteristics of the plasmonic solar cell were supplied to the simulation.

As can be seen in FIGS. 2A and 2B, the agreement between the simulation and the experimental results is generally close. Differences between the two may be due to the assumed geometries or variations in the optical constants, particularly in the a-Si:H layer. Amorphous silicon's complex refractive index is known to vary with hydrogenation, and may also vary throughout the thickness of the layer. The agreement between simulation and experiment is less accurate on the blue side of the spectrum, which is reasonable due to an assumption of the simulation that every photon produces one collected electron. At the shorter wavelengths, the collection process is inefficient, and the number of collected electrons will be a smaller percentage of the total generated carriers.

The experimental cells in FIG. 2 have efficiencies of 5.8% (comparative example, Asahi texture) and 6.6% (first embodiment, 500 nm pitch periodic) for a greater than 13% increase in efficiency. Based on a comparison of the experimental measurements shown in FIGS. 2A and 2B, it is evident that the periodically patterned cell exhibits slightly higher photocurrents from 350-550 nm, with substantially higher photocurrents from 550-650 nm. In the longer red portions from 650 nm to the band edge at 800 nm, the photocurrent alternately exceeds and falls below the photocurrent of the Asahi cell. The periodically patterned cell exhibits several peaks in both photocurrent and simulated absorption, particularly on the red-side of the band. Previous experimental measurements of angle-resolved photocurrent showed that these experimental peaks are due to waveguide modes which enhance absorption in the semiconductor.

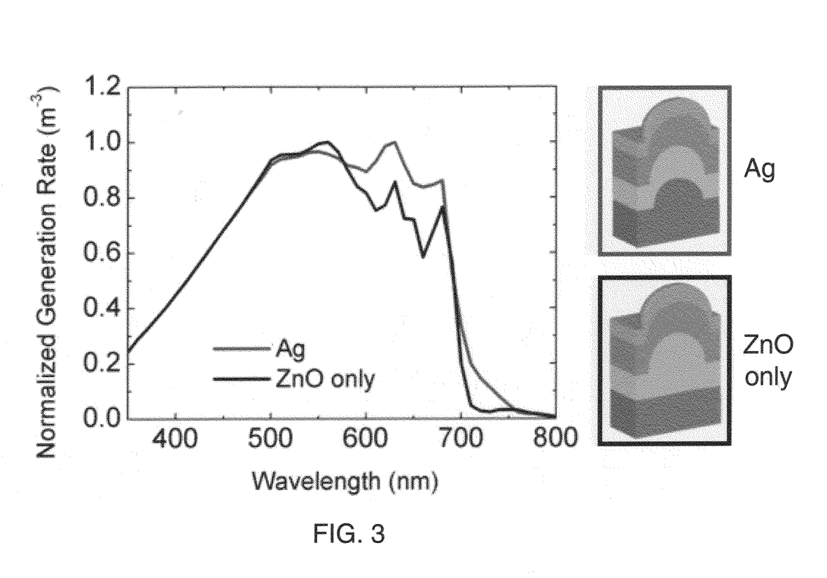

Based on simulations, the nano-scale features on the back contact surface appear to produce significantly increased absorption in the longer wavelengths, as seen in FIG. 3, where the carrier generation rate for a solar cell having back contact surface with nano-scale patterns (labeled “Ag” and shown in green) is markedly greater than that of a solar cell with a flat back contact surface (labeled “ZnO only” and shown in black) in a wavelength range between about 550 nm and 750 nm.

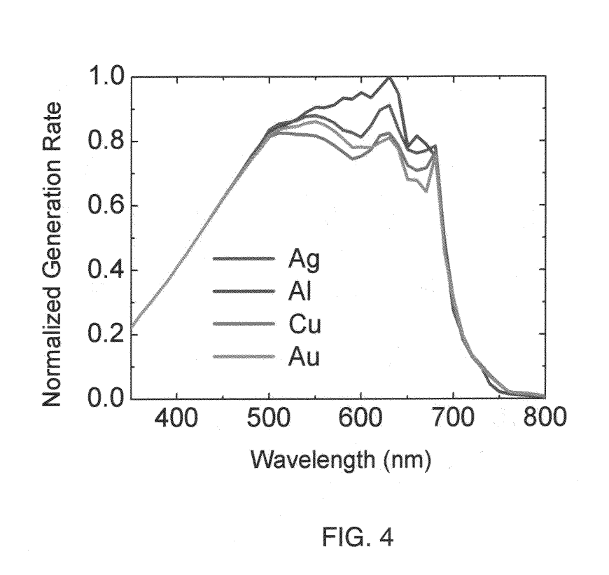

The type of metal used in the back-contact layer can also have an effect on the carrier generation rate of the solar cell. FIG. 4 is a graph illustrating normalized generation rates for gold, silver, copper, and aluminum having nano-scale features 300 nm in diameter and at a pitch of 500 nm. As expected, the four metals show substantially identical response from 350-500 nm, but the absorption response is quite different from 500-700 nm. While many of the spectral features occur at the same wavelengths, the absorption in the a-Si:H when Al is used as the back contact is much higher than with Ag, which, in turn, provides higher absorption than both Cu and Au. Al is also a known back contact material for a-Si:H with good electrical properties, and is used in some embodiments due to its lower cost in comparison to, for example, Ag.

The diameters and pitch of the nano-scale features can be varied according to other embodiments of the present invention.

Simulations were performed for a solar cell having a silver back contact layer with nano-scale features 300 nm in diameter. FIG. 5A is a graph illustrating absorption enhancement as a function of pitch and incident wavelength, where the enhancement is calculated relative to the absorption in a simulated Asahi reference cell according to embodiments of the present invention. Colors indicate the performance of the plasmonic solar cell as compared to a solar cell having a rough back contact, where darker blues indicate lower performance, light blue indicates approximately equal performance, yellow indicates slightly higher performance, and red indicates significantly enhanced performance. As can be seen in FIG. 5A, a considerably larger portion of the wavelength spectrum (i.e., looking along a vertical line) is yellow or red in the portion of the graph associated with shorter pitches (i.e., the left side of the graph) than longer pitches (i.e., the right side of the graph) therefore indicating that shorter pitches are generally more efficient over a wide bandwidth than longer pitches.

FIG. 5B is a graph of simulated solar spectrum integrated enhancement in absorption as a function of pitch for a solar cell with a back contact layer having nano-scale features 300 nm in diameter according to embodiments of the present invention. This is calculated by integrating over each vertical line in FIG. 5A. The scale in FIG. 5A is relative to the simulated Asahi cell and the arrows depict the pitches that were built and experimentally tested. The experimental results were in line with the simulated data, with the device with 500 nm pitch nano-scale features showing a 10% improvement over the Asahi reference cell, and the 700 nm pitch cell showing markedly suppressed output. At a pitch of 400 nm, the graph shows a peak enhancement value of 15% over the randomly textured cell.

The spacing of the nano-scale features in the upper layers of the structure such as the first electrode 18 also affect the efficiency of absorption. As can be seen in FIGS. 2A and 2B, a solar cell according to the first embodiment of the present invention which includes nano-scale features (in FIG. 2B) has improved EQE over the comparative example having only rough surfaces (in FIG. 2A) near the blue end of the spectrum. However, incident sunlight in the range of 350 to 500 nm generally does not reach the back contact and therefore the nano-scale features on the back contact will not have an effect on absorption at those wavelengths.

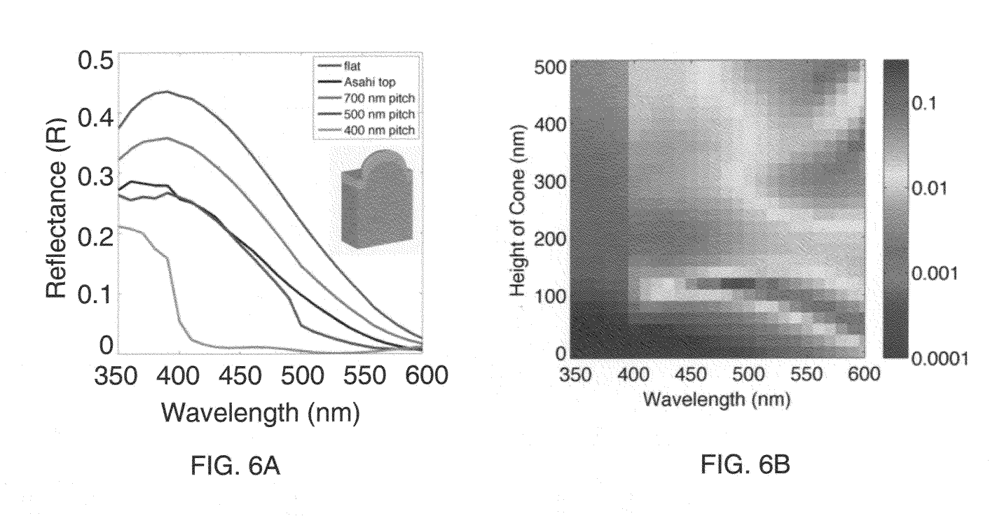

FIG. 6A is a graph comparing the calculated reflectances of solar cells in which only the top surfaces are textured. The compared surfaces are flat, rough (Asahi glass texture), and nano-scale structures having 700 rim, 500 nm, and 400 nm pitches according to embodiments of the present invention. To remove the effects of the back contact or the film thickness, the simulation used a semi-infinite slab (e.g., where only the upper surface of the solar cell was simulated and reflections from layers below the semiconductor layer were ignored) of a-Si:H coated in 80 nm of ITO, where the top is was structured with ITO hemiellipsoids having a diameter of 400 nm and a height of 100 nm, as assumed in previous calculations. (As described above, the diameters of the nano-scale structures of the upper layers may be larger than those of the layers below them.) As can be seen in FIG. 6, the trend is consistent with the other simulations: the closely packed, curved surfaces show reduced reflection relative to the flat and Asahi reference cells, and the reflection from these curved surfaces increases with longer wavelengths. In addition, the reflection appears to be at a minimum value when the wavelength is equal to the pitch.

FIG. 6B is a graph illustrating the change in reflection as the height of the nano-scale structures (or “cone”) is varied from 0 nm (flat film) to 500 nm in the 400 nm pitch case. For wavelengths longer that the pitch, there is complex behavior with regions of high and low reflection, while at wavelengths shorter than the pitch the reflection strictly decreases with increasing pitch. Based on the calculations shown in FIG. 6B, according to embodiments of the present invention under these conditions (400 nm pitch and nano-scale structures with a diameter of 400 nm), it appears that the reflections in the daylight spectrum are minimized at cone height of about 100 nm where there is a relatively broad area of low reflection in the range of 450-550 nm.

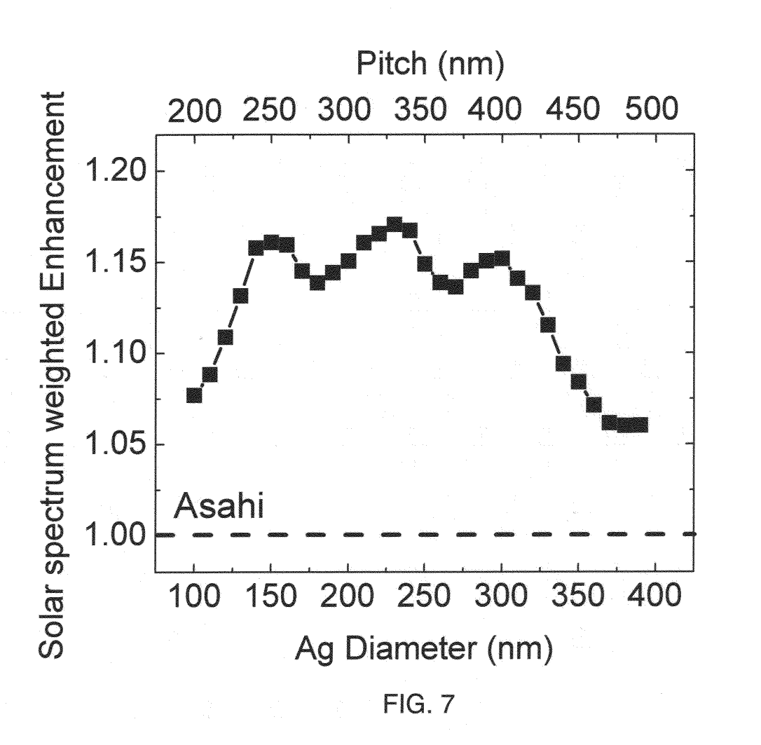

The calculation of solar spectrum integrated enhancement as a function of pitch described above and shown in FIG. 5B was repeated for a number of other diameters. In particular, the diameters of the nano-scale structures on an Ag back contact layer was varied from 100 nm to 400 nm and the spectrum weighted enhancement at the optimum pitch is shown in FIG. 7. As can be seen in FIG. 7, although all of the nano-scale patterned back contact layers having features with diameters from 100 nm to 400 nm show at least a 5% increase in enhancement over a rough (Asahi) patterned surface, simulations predict that an absorption enhancement of 17% is possible at a diameter of approximately 230 nm and a pitch of approximately 330 nm. In addition, enhancements of about 15% are possible at a diameter of approximately 150 nm and a pitch of approximately 250 nm and at a diameter of approximately 300 nm and a pitch of approximately 400 nm.

Therefore, based on experimentally realizable open circuit voltages and fill factors, this predicts an ultrathin, a-Si:H solar cell with a greater than 10% efficiency. In this specification, the term “ultrathin semiconductor” includes semiconductors having a thickness in the range of 100's of nm to approximately 1-2 μm, depending on the characteristics of the semiconductors being used. For example, an a-Si:H solar cell may have a semiconductor layer with a thickness from about 100 nm to about 400 nm.

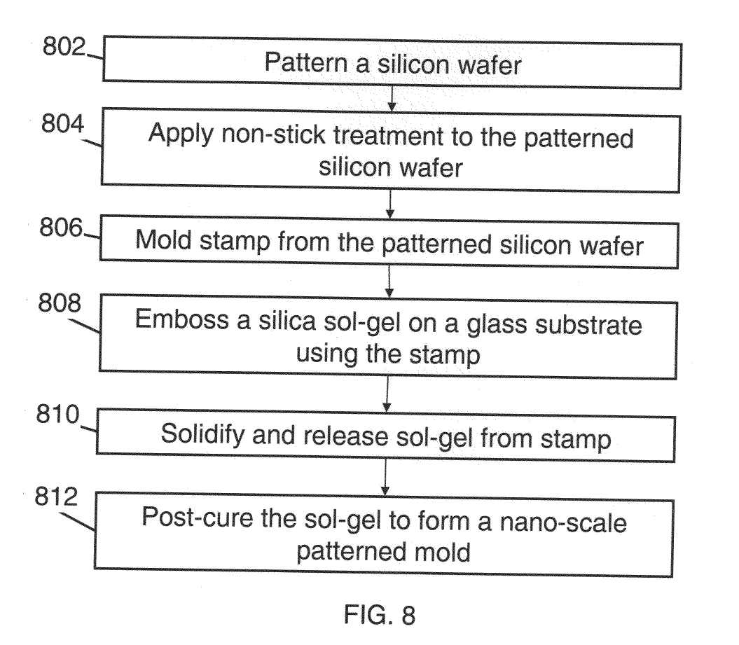

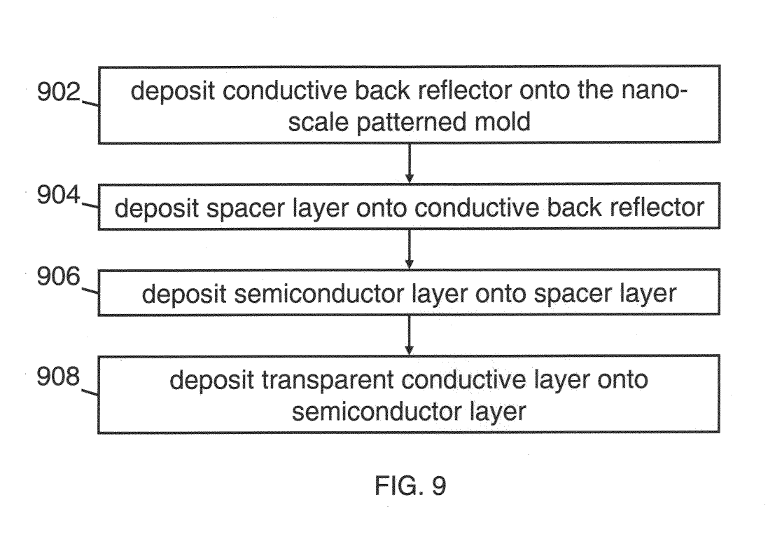

According to one embodiment of the present invention, the nanostructures are fabricated via a form of nanoimprint lithography—substrate conformal imprint lithography (SCIL)—although other fabrication techniques. (e.g., evaporating through an anodic alumina template; island evaporation (anneal thin firms of silver under forming gas), self assembly methods, block co-polymer assembly, nanosphere lithography, and similar techniques) may also be used. SCIL is a nanoimprint lithography technique in which a sequence of grooves is used to sequentially evacuate and use capillary forces to pull a stamp into, e.g., a sol-gel resist, so that there are substantially no air inclusions and results in a substantially defect free print. FIG. 8 is a flowchart illustrating a method of forming a nano-scale patterned mold according to an embodiment of the present invention. FIG. 9 is a flowchart illustrating a method of fabricating a plasmonic solar cell according to an embodiment of the present invention.

1. A master Si wafer is patterned using, for example, electron beam lithography (802).

2. The surface of the Si wafer is modified with a non-stick treatment (e.g., treating it with Si—F) to reduce adhesion between the PDMS stamp and the wafer (804), and a stamp (e.g., a bilayer composite PDMS stamp) is molded from the wafer (806). The bilayer composite PDMS stamp includes a thin high modulus polydimethylsiloxane layer that holds the nanopatterns and a low modulus PDMS layer that binds the nanopatterns to a 200 μm thick glass support for in-plane stiffness.

3. The stamp is used to emboss a 100 nm thick layer of silica sol-gel on AF45 glass substrates using substrate conformal imprint lithography (SCIL) (808). The sol-gel layer is solidified at room temperature by forming a silica network (essentially a patterned glass) (810), while reaction products diffuse into the rubber stamp.

4. After stamp release, the sol-gel is post cured at 200° C. (812).

5. The back contact layer and spacer layer (e.g., 200 nm of Ag and 130 nm of ZnO:Al, respectively) are deposited (e.g., sputtered) over the patterned sol-gel on glass substrates (902 and 904).

6. A semiconductor layer (e.g., n-i-p a-Si:H layers) is deposited on the spacer layer (906) using, e.g., 13.56 MHz plasma enhanced chemical vapor deposition.

7. A first electrode is deposited on top of the semiconductor layer (908). E.g., an array of 4×4 mm² squares of ITO is sputtered through a contact mask and Au finger contacts are evaporated over the ITO using a second contact mask.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

For example, one feature of the design according to embodiments of the present invention is that both the back metal and the top semiconductor/conducting oxide interfaces include nanopatterns. This can be accomplished in a number of ways:

1. The metal patterns can be defined by sputtering or other suitable processes over cured silica sol-gel on glass as outlined above, and each of the successive layers as defined above is deposited conformally, leading to natural texture on the top interface.

2. The patterns can be fabricated via the superstrate configuration. Rather than step (5) in the fabrication procedure described above, the cured silica sol-gel is coated with conducting oxide (e.g., ITO) to form the first electrode, and the cell is built conformally in reverse (e.g., next depositing the semiconductor layer, the spacer layer, and the back contact layer, in the order given) so that the back metal surface is also nanostructured. In such a case, the characteristics of these steps may be substantially similar to the fabrication in the substrate configuration.

3. The two surfaces can be patterned independently. The first step patterns the silica sol-gel and overcoats with either metal or conducting oxide (depending on whether the deposition is substrate or superstrate type). The semiconductor can then be deposited over the nanopatterns so that the top surface is flat. A second patterned stamp can then be used to define features on the top surface via etching or liftoff processes.

Other methods besides SCIL may be used to define the initial nano-scale features, including depositing through anodized aluminum oxide templates.

Steps (1)-(5) may be similar for many different semiconductor materials, or the nanopatterns may be applied after deposition as in “3”, described directly above.

In addition, other semiconductor materials such as CIGS, CdTe, polymers, crystalline Si, microcrystalline Si, GaAs, Ge, and other suitable materials may be used in place of a-Si:H in the semiconductor layer. Tandem cells may also be used, such as a microcrystalline Si/amorphous Si geometry. In these other semiconductors, a standard p-n junction may be used in place of a p-i-n junction or n-i-p junction as used with a-Si:H.

The thickness of the intrinsic layer of the semiconductor layer may vary from 90 nm to 250 nm. In some embodiments of the present invention, the p-layer and the n-layer are 20 nm and 25 nm thick, respectively. A thicker semiconductor may further distort or smooth the nano-scale features as described above. However, the nano-scale features may be better defined by printing patterns on the surface of the front electrode after fabrication.

The thickness of the spacer layer is not limited to 130 nm and may, for example, have a thickness from 10 nm to 800 nm without significantly affecting the performance of the cell.

The thickness of the top electrode (which may include a transparent conductor such as ITO) may be thicker or thinner than 80 nm (e.g., 40 nm to 150 nm or even 300 nm) and may be varied to reduce parasitic absorption and to reduce reflections.

The top electrode may also be made of other transparent conductive materials such as zinc oxide (ZnO), indium zinc oxide) or may be a nanowire mesh electrode (made of a conductive material such as silver) that can be spin coated or other suitable light transmissive conductive layer.

In the embodiments described above, the nano-scale features are laid out in a square grid. However, in other embodiments of the present invention, the nano-scale features may be laid out in hexagonal, quasi-crystal grids (e.g., a Penrose tiling), quasi-random lattices, etc.

Other materials such as thermosetting polymers and UV-curable resists may also be used in place of the sol-gel.

In addition, the substrate need not be AF45 glass—other glasses, plastic, stainless steel, or other materials may also be used as the substrate.

What is claimed is:

1. A solar cell comprising:
a nano-scale patterned back contact layer;
a spacer layer on the nano-scale patterned back contact layer;
a semiconductor layer on the spacer layer; and
a light transmissive first electrode on the semiconductor layer.

2. The solar cell of claim 1, wherein the nano-scale patterned back contact layer has a plurality of rounded cylinders arranged in a grid.

3. The solar cell of claim 2, wherein each of the plurality of rounded cylinders of the nano-scale patterned back contact layer has a diameter in the range of 100 nm to 400 nm and are arranged at a pitch in the range of 200 nm to 500 nm, wherein the diameter is smaller than the pitch.

4. The solar cell of claim 3, wherein the rounded cylinders of the nano-scale patterned back contact layer have a height of approximately 100 nm.

5. The solar cell of claim 3, wherein the rounded cylinders of the nano-scale patterned back contact layer have a diameter of approximately 300 nm and are arranged at a pitch of approximately 400 nm.

6. The solar cell of claim 3, wherein the rounded cylinders of the nano-scale patterned back contact layer have a diameter of approximately 230 nm and are arranged at a pitch of approximately 330 nm.

7. The solar cell of claim 3, wherein the rounded cylinders of the nano-scale patterned back contact layer have a diameter of approximately 150 nm and are arranged at a pitch of approximately 250 nm.

8. The solar cell of claim 3, wherein the transparent conductive layer has a nano-scale patterned plurality of rounded cylinders, each of the nano-scale patterned plurality of rounded cylinders of the transparent conductive layer overlying a corresponding rounded cylinder of the plurality of rounded cylinders of the nano-scale patterned back contact layer.

9. The solar cell of claim 1, wherein the nano-scale patterned back contact layer is metallic.

10. The solar cell of claim 9, wherein the nano-scale patterned back contact layer comprises a metal selected from the group consisting of silver, gold, copper, and aluminum, and combinations thereof.

11. The solar cell of claim 1, wherein the spacer layer comprises ZnO:Al.

12. The solar cell of claim 1, wherein the spacer layer is transparent.

13. The solar cell of claim 1, wherein the semiconductor layer comprises a-Si:H.

14. The solar cell of claim 1, wherein the semiconductor layer comprises CIGS.

15. The solar cell of claim 1, wherein the semiconductor layer comprises CdTe.

16. The solar cell of claim 1, wherein the transparent conductive layer comprises ITO.

17. The solar cell of claim 1, wherein the first electrode further comprises a plurality of finger contacts.

18. A method of manufacturing a solar cell, the method comprising:
depositing a metal onto a nano-scale patterned mold to form a nano-scale patterned metal layer;
depositing a spacer layer onto the nano-scale patterned metal layer;
depositing n-i-p semiconductor layers on the spacer layer;
depositing an array of squares of a transparent conductive layer through a first contact mask to form a transparent conductor layer; and
depositing a plurality of finger contacts over the transparent conductive layer using a second contact mask.

19. The method of claim 18, wherein the depositing the metal, depositing the spacer layer, and depositing the transparent conductive layer is performed by sputtering.

20. The method of claim 18, wherein the nano-scale patterned metal layer comprises a plurality of rounded cylinders arranged in a grid.

21. The method of claim 20, wherein each of the plurality of rounded cylinders has a diameter from 100 nm to 400 nm and are spaced at a pitch from 200 nm to 500 nm, wherein the diameter is smaller than the pitch.

22. The method of claim 18, further comprising constructing the nano-scale patterned mold, the constructing the nano-scale patterned mold comprising:
patterning a silicon wafer using electron beam lithography;
applying a non-stick treatment to a surface of the silicon wafer;
molding a bilayer composite PDMS stamp from the silicon wafer;
embossing a silica sol-gel on a glass substrate with the bilayer composite PDMS stamp using substrate conformal imprint lithography (SCIL);
releasing the sol-gel from the stamp; and
post curing the sol-gel to form the nano-scale patterned mold.

23. The method of claim 22, wherein the bilayer composite PDMS stamp comprises a thin high modulus polydimethylsiloxane layer having nanopatterns and a low modulus PDMS layer configured to bind the thin high modulus polydimethylsiloxane layer to a glass support.
